(19) United States
(12) Patent Application Publication
(10) Pub. No.: US 2010/0127897 A1
(43) Pub. Date: May 27, 2010

(54) MULTI-STATUS KEY ASSEMBLY

(75) Inventor: JIANG LONG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (Hong Kong) Limited, Kowloon (HK)

(21) Appl. No.: 12/389,490

(22) Filed: Feb. 20, 2009

(30) Foreign Application Priority Data
Nov. 27, 2008 (CN) 200810305802.8

(51) Int. Cl. H03K 17/94

(52) U.S. Cl. 341/20

(57) ABSTRACT

A multi-status key assembly is described. The multi-status key assembly includes a pressing body, a support member and a pressing cover. The support member is disposed between the pressing cover and the pressing body. A pressing pole and direction pressing poles protrude from the pressing body.

### BACKGROUND

1. Field of the invention

The present invention relates to key assemblies and, particularly, to a multi-status key assembly used in a portable electronic device.

2. Description of related art

A portable electronic device (e.g., mobile phone or personal digital assistant, PDA) usually has a key assembly including four direction keys and an enter key. The enter key is typically arranged among the four direction keys.

However, in use of such key assembly, a user usually has to move his/her fingers from one key to another, thus reducing the input efficiency.

Therefore, there is room for improvement within the art.

### BRIEF DESCRIPTION OF THE DRAWINGS

Many aspects of a multi-status key assembly can be better understood with reference to the following drawings. These drawings are not necessarily drawn to scale, the emphasis instead being placed upon clearly illustrating the principles of the present multi-status key assembly. Moreover, in the drawings like reference numerals designate corresponding sections throughout the several views.

FIG. 1 is an exploded, isometric view of a multi-status key assembly, according to an exemplary embodiment.

FIG. 2 is similar to FIG. 1, but viewed from another aspect.

FIG. 3 is an assembled view of the multi-status key assembly shown in FIG. 1.

FIG. 4 is a cross-sectional view of FIG. 3 showing one state of the use of the multi-status key assembly shown in FIG. 1.

FIG. 5 is a cross-sectional view of FIG. 3 showing another state of the use of the multi-status key assembly shown in FIG. 1.

### DETAILED DESCRIPTION OF EXEMPLARY EMBODIMENT

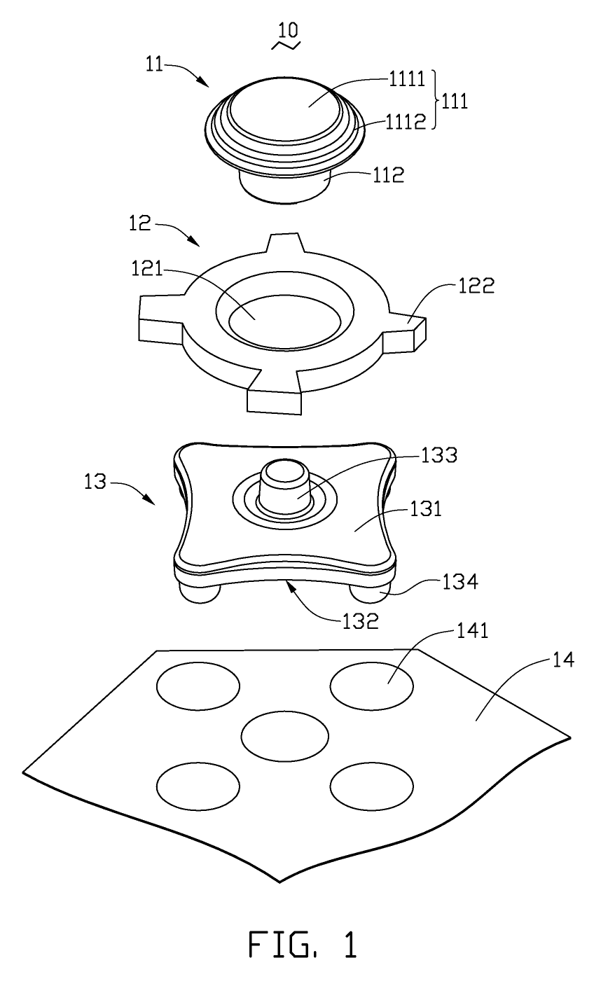

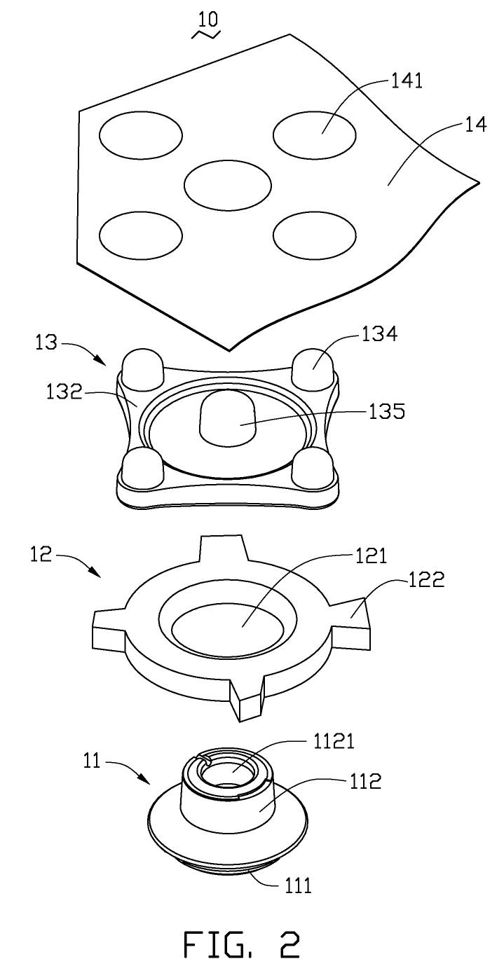

FIGS. 1 through 3 show an exemplary embodiment of a multi-status key assembly 10. The key assembly 10 includes a pressing cover 11, a support member 12, a pressing body 13 and a printed circuit board 14. The support member 12 is disposed between the pressing cover 11 and the pressing body 13. The pressing body 13 is positioned on the printed circuit board 14.

The pressing cover 11 has a T-shaped cross-section, including an operating portion 111 and a connecting portion 112 connected to the operating portion 111. The operating portion 111 includes an operating surface 1111 and a tapered brim 1112. The tapered brim 1112 is connected to a periphery of the operating surface 1111. The operating surface 1111 and the tapered brim 1112 are configured to be pressed by a user's finger. The connecting portion 112 is a hollow column, defining a cavity 1121 therein.

The support member 12 generally includes a through hole 121 defined at a central area thereof and several fastening blocks 122 protruding from a peripheral wall of the support member 12. The fastening blocks 122 are fixed to a body section of a portable electronic device. The through hole 121 is configured to receive the connecting portion 112 of the pressing cover 11.

The pressing body 13 includes a top surface 131 and an opposite bottom surface 132. A connecting post 133 protrudes from the top surface 131, corresponding to the connecting portion 112. An outer diameter of the connecting post 133 is substantially equal to an inner diameter of the cavity 1121. The bottom surface 123 has a pressing pole 135 protruding from a center. Four direction pressing poles 134 also protrude from the bottom surface 132, surrounding the pressing pole 135. A height of the pressing pole 135 is bigger than each direction pressing pole 134.

The printed circuit board 14 forms five electrical contacts 141 corresponding to the pressing pole 135 and the four direction pressing poles 134. Each electrical contact 141 has an arcuate surface with a good resilience.

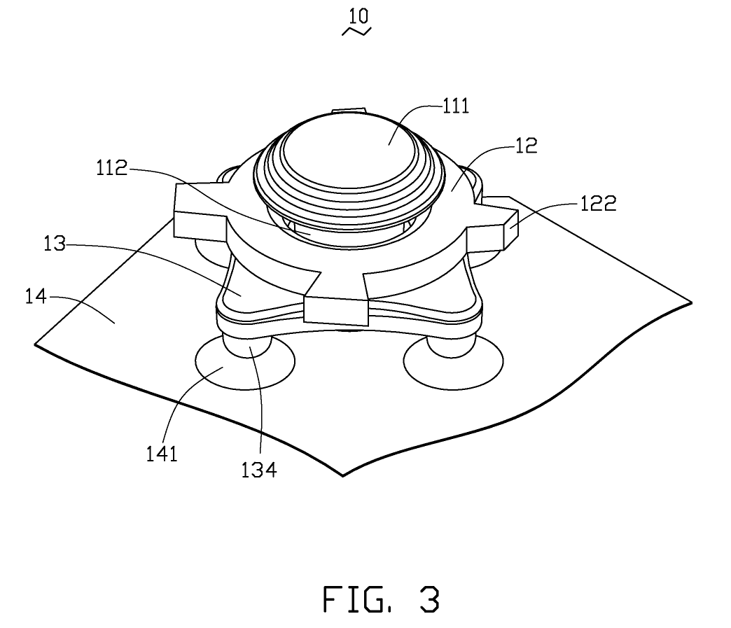

Referring to FIG. 3, in assembly, the connecting portion 112 is inserted into the through hole 121 from one side of the support member 12. The connecting post 133 of the pressing body 13 is inserted into the cavity 1121 and combined with the connecting portion 112 on the other side of the support member 12. The printed circuit board 14 is placed adjacent to the pressing body 13, with the pressing pole 135 and the four direction pressing poles 134 being aligned with the corresponding electrical contacts 141. At this time, the four direction pressing poles 134 are spaced from their corresponding electrical contacts 141, while the pressing pole 135 slightly contacts its corresponding electrical contacts 141, thus supporting the pressing body 13.

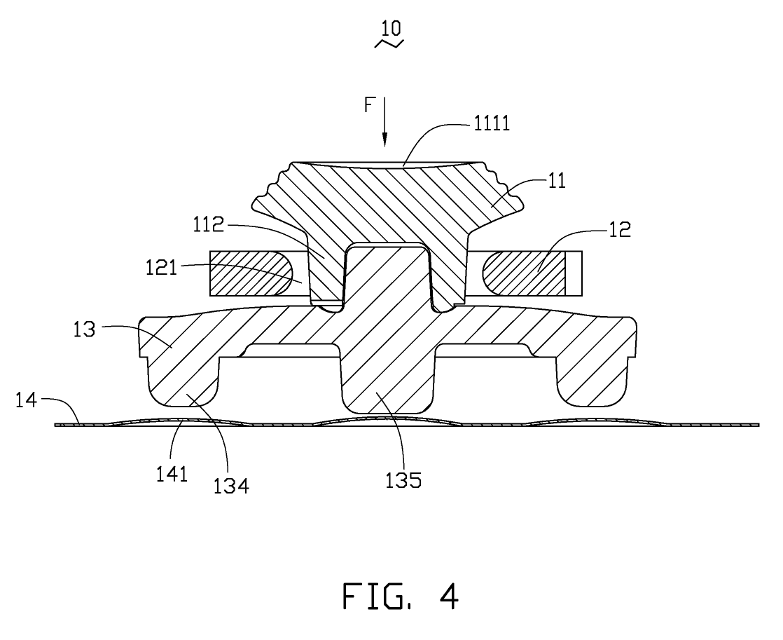

Referring to FIG. 4, when an external force F is applied on the operating surface 1111 towards the printed circuit board 14, the pressing cover 11 and the pressing body 13 move towards the printed circuit board 14. Since the pressing pole 135 is higher than the direction pressing poles 134, the pressing pole 135 presses its corresponding electrical contact 141 to input a corresponding signal, while the four direction pressing poles 134 are still spaced from their corresponding electrical contacts 141. When the external force F is removed, the electrical contact 141 returns/restores the pressing pole 135 to the previous position.

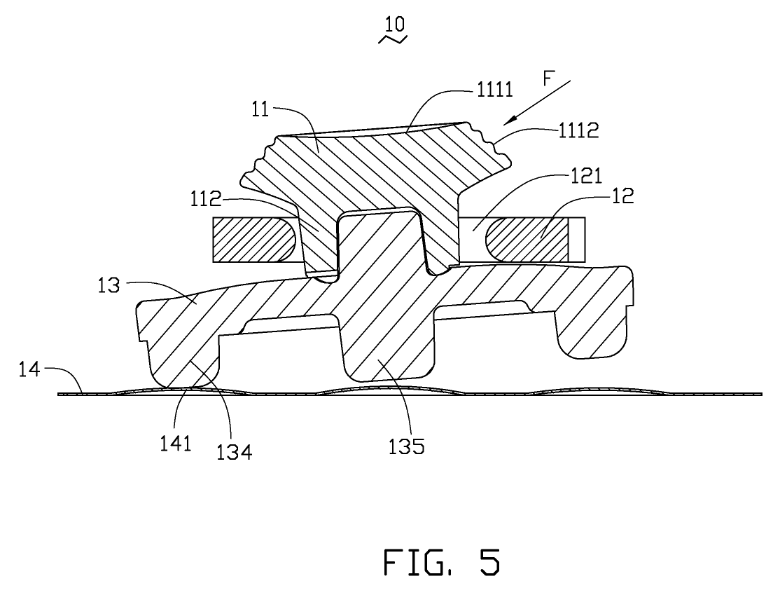

Referring to FIG. 5, when an external force F is applied on the tapered brim 1112 towards one direction pressing pole 134, the pressing cover 11 and the pressing body 13 swing about the support member 12. At this time, the above-mentioned direction pressing pole 134 advances more than the other three direction pressing poles 134. Thus the direction pressing pole 134 presses its corresponding electrical contact 141 and inputs a corresponding signal, while the other three direction pressing poles 134 are spaced from the printed circuit board 14 and the pressing pole 135 still slightly contacts its corresponding electrical contact 141. Once the external force F is removed, the electrical contact 141 returns/restores the direction pressing pole 134 to the previous position.

Users can operate the pressing pole 135 and the four direction pressing poles 134 via the pressing body 13, thus avoiding frequent jumps of fingers between different keys and improving the input efficiency of the multi-status key assembly 11.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of sections within the principles of the invention to the full extent indicated by the broad general meaning of the terms, in which the appended claims are expressed.

What is claimed is:

1. A multi-status key assembly, comprising:
a pressing body;
a support member; and
a pressing cover, the support member being disposed between the pressing cover and the pressing body, a pressing pole and a plurality of direction pressing poles protruding from the pressing body.

2. The multi-status key assembly as claimed in claim 1, wherein the number of the direction pressing poles is four, the four direction pressing poles surrounding the pressing pole.

3. The multi-status key assembly as claimed in claim 2, wherein the height of the pressing pole is bigger than the four direction pressing poles.

4. The multi-status key assembly as claimed in claim 2, wherein the pressing body includes a top surface and a bottom surface, a connecting post protruding form the top surface, the pressing cover defining a cavity, the connecting post is received in the cavity and combined with the pressing cover.

5. The multi-status key assembly as claimed in claim 4, wherein the pressing pole and the four direction pressing poles protrude from the bottom surface.

6. The multi-status key assembly as claimed in claim 4, wherein the pressing cover includes an operating portion and a connecting portion connected to the operating portion, the cavity being defined in the connecting portion therein.

7. The multi-status key assembly as claimed in claim 4 further comprising a printed circuit board, wherein the printed circuit board arranges a plurality of electrical contacts corresponding to the pressing pole and the direction pressing poles.

8. The key assembly as claimed in claim 7, wherein each electrical contact has a resilient arcuate surface.
